(19) United States
(12) Patent Application Publication
(10) Pub. No.: US 2025/0072182 A1
(43) Pub. Date: Feb. 27, 2025

(54) DISPLAY DEVICE INCLUDING A SEMICONDUCTOR LIGHT EMITTING DEVICE

(71) Applicant: LG ELECTRONICS INC., Seoul (KR)

(72) Inventors: Seonock KIM, Seoul (KR); Hwankuk YUH, Seoul (KR)

(73) Assignee: LG ELECTRONICS INC., Seoul (KR)

(21) Appl. No.: 18/808,988

(22) Filed: Aug. 19, 2024

(30) Foreign Application Priority Data
Aug. 24, 2023 (KR) 10-2023-0111347

(51) Int. Cl. H01L 33/60; H01L 25/075; H01L 33/52

(52) U.S. Cl. CPC H01L 33/60; H01L 25/0753; H01L 33/52

(57) ABSTRACT

A display device including the semiconductor light emitting device according to an embodiment including a planarization layer disposed on the semiconductor light emitting device, a first opaque filler disposed to be spaced apart on the planarization layer, and a light reflective filling layer disposed around the semiconductor light emitting device, wherein the light reflective filling layer is positioned lower than the top surface of the semiconductor light emitting device.

### CROSS-REFERENCE TO RELATED APPLICATIONS

The present application claims the benefits of priority to Korean Patent Application No. 10-2023-0111347, filed on Aug. 24, 2023, which is incorporated herein by reference in their entirety.

### THE BACKGROUND

### 1. The Field

The embodiment relates to a display device including a semiconductor light emitting device.

### 2. Description of the Related Art

Large-area displays include liquid crystal displays (LCDs), OLED displays, and Micro-LED displays.

The micro-LED display is a display using a micro-LED, which is a semiconductor light emitting device having a diameter or cross-sectional area of 100 μm or less, as a display device.

The Micro-LED display has an excellent performance in many characteristics such as contrast ratio, response speed, color reproduction rate, viewing angle, brightness, resolution, life, luminous efficiency and luminance because it uses the micro-LED which is a semiconductor light emitting device, as a display device.

In particular, the micro-LED display has the advantage of being able to freely adjust the size and resolution and to implement a flexible display because the screen may be separated and combined in a modular manner.

However, there is a technical problem in that it is difficult to quickly and accurately transfer the semiconductor light emitting device to the display panel because more than millions of semiconductor light emitting devices are required for a large micro-LED display.

Transfer technologies that have been recently developed include a pick and place process, a laser lift-off method, or a self-assembly method.

Meanwhile, in a micro-LED display device based on internal technology, a black matrix was placed on a top of the micro-LED. However, when a black matrix is placed on the top of the micro-LED, a problem of a difference in luminance depending on a viewing angle has been studied.

On the other hand, in the internal technology, the black matrix is arranged to surround the micro-LED. In this case, the problem of the black matrix absorbing light and reducing luminance was studied.

### THE SUMMARY

One of the technical objects of the embodiment is to improve light efficiency in the display device.

Additionally, another technical object of the embodiment is to improve light uniformity.

Additionally, one of the technical objects of the embodiment is to compensate for the decrease in luminance caused by the black filler.

The technical objects of the embodiments are not limited to those described in this item and include those that may be understood through the description of the invention.

A display device including a semiconductor light emitting device according to an embodiment may include a substrate; a semiconductor light emitting device disposed on the substrate; a planarization layer disposed on the semiconductor light emitting device; one or more first opaque fillers disposed to be spaced apart on the planarization layer; and a light reflective filling layer disposed around the semiconductor light emitting device, wherein the light reflective filling layer may be located lower than an upper surface of the semiconductor light emitting device.

Additionally, in an embodiment, a side surface of the semiconductor light emitting device may include a first area in contact with the light reflective filling layer and a second area in contact with the planarization layer.

Additionally, in an embodiment, the semiconductor light emitting device may be located below between the one or more first opaque fillers.

Additionally, in an embodiment, the semiconductor light emitting device may not vertically overlap the one or more first opaque filler.

Additionally, in an embodiment, a horizontal width of the light reflective filling layer may be greater than a distance between the first opaque fillers.

Additionally, the embodiment may further include a reflective film disposed below the semiconductor light emitting device.

Additionally, in an embodiment, a horizontal width of the reflective film may be greater than a distance between the first opaque fillers that are spaced apart.

Additionally, in an embodiment, a lower surface of the light reflective filling layer may be located at the same height as the lower surface of the semiconductor light emitting device, and the upper surface of the light reflective filling layer may be located lower than the active layer of the semiconductor light emitting device.

Additionally, in an embodiment, a thickness of the light reflective filling layer may be smaller than a thickness of the semiconductor light emitting device.

Additionally, the embodiment may further include one or more second opaque fillers disposed below the one or more first opaque fillers.

Additionally, in an embodiment, the one or more second opaque fillers may be disposed on the planarization layer.

Further, a display device including a semiconductor light emitting device according to an embodiment may include a substrate, a semiconductor light-emitting device disposed on the substrate, a planarization layer disposed on an upper side of the semiconductor light-emitting device, one or more first opaque fillers on the planarization layer, one or more second opaque fillers disposed below the first opaque fillers and disposed in the planarization layer and a light reflective filling layer disposed around the semiconductor light-emitting device.

Also, the light reflective filling layer may be disposed lower than an upper surface of the semiconductor light-emitting device.

Also, the light reflective filling layer may have a reflectivity of 60% or more.

Also, the embodiment may further include a second planarization layer disposed between the one or more first opaque fillers and the one or more second opaque fillers.

Also, the embodiment may further include a reflective film disposed under the semiconductor light-emitting device.

A display device including the semiconductor light emitting device according to an embodiment has the technical effect of improving light uniformity.

For example, the embodiment may reduce the difference in luminance depending on the viewing angle by disposing a light reflective filling layer surrounding the semiconductor light emitting device.

Additionally, the embodiment has a technical effect of improving the brightness of the display device.

For example, as the light reflective filling layer is located lower than the semiconductor light emitting device, light emitted from the sides and bottom of the semiconductor light emitting device may be reflected upward to improve luminance.

The technical effects of the embodiments are not limited to those described in this item and include those that may be understood through the description of the invention.

### BRIEF DESCRIPTION OF THE DRAWINGS

FIG. 1 is an exemplary diagram of a living room of a house where a display device according to an embodiment is placed.

FIG. 2 is a block diagram schematically showing a display device according to an embodiment.

FIG. 3 is an enlarged view of the first panel area in the display device of FIG. 1.

FIG. 4 is a cross-sectional view taken along line B1-B2 in area A2 of FIG. 3.

FIG. 5A is a conceptual diagram of a display device being studied internally.

FIG. 5B is a graph showing the luminance according to the viewing angle of the display device of FIG. 5A.

FIG. 6A is a conceptual diagram of a display device being studied internally.

FIG. 6B is a graph showing the luminance according to the viewing angle of the display device of FIG. 6A.

FIG. 7 is a conceptual diagram of a display device including the semiconductor light emitting device according to an embodiment.

FIG. 8 is a cross-sectional view showing the semiconductor light emitting device of FIG. 7 in detail.

FIG. 9 is a conceptual diagram of a display device including the semiconductor light emitting device according to a second embodiment.

FIG. 10 is a conceptual diagram of a display device including the semiconductor light emitting device according to a third embodiment.

### THE DETAILED DESCRIPTION

Hereinafter, embodiments disclosed in the present description will be described in detail with reference to the accompanying drawings. The suffixes ‘module’ and ‘part’ for components used in the following description are given or mixed in consideration of ease of specification, and do not have a meaning or role distinct from each other by themselves. Also, the accompanying drawings are provided for easy understanding of the embodiments disclosed in the present specification, and the technical ideas disclosed in the present specification are not limited by the accompanying drawings. Also, when an element, such as a layer, area, or substrate, is referred to as being ‘on’ another component, this includes that it is directly on the other element or there may be other intermediate elements in between.

The display device described in this specification may include a digital TV, a mobile phone, a smart phone, a laptop computer, a digital broadcasting terminal, a personal digital assistant (PDA), a portable multimedia player (PMP), a navigation, a Slate PC, a Tablet PC, an Ultra-Book, a desktop computer, and the like. However, the configuration according to the embodiment described in this specification may be applied to a device capable of displaying even a new product type to be developed in the future.

Hereinafter, a light emitting device according to an embodiment and a display device including the same will be described.

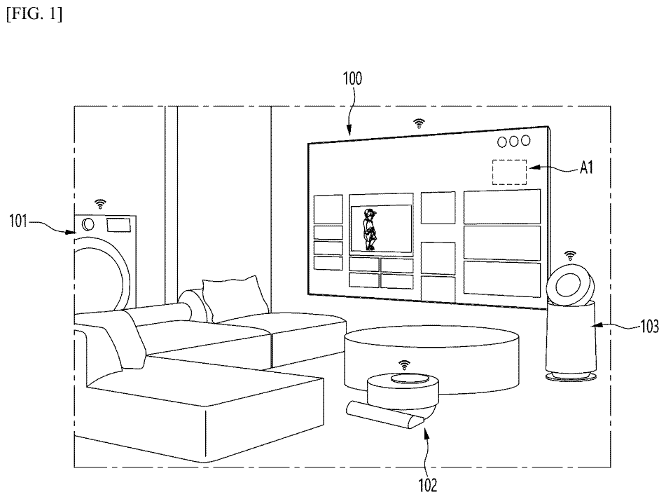

FIG. 1 shows a living room of a house where a display device 100 according to an embodiment is placed.

The display device 100 of the embodiment may display the status of various electronic products such as a washing machine 101, a robot vacuum cleaner 102, and an air purifier 103, may communicate with each electronic product based on IOT and may control each electronic product based on the user's setting data.

The display device 100 according to the embodiment may include a flexible display manufactured on a thin and flexible substrate. Flexible displays may bend or curl like paper while maintaining the characteristics of existing flat displays.

In a flexible display, visual information may be implemented by independently controlling the emission of unit pixels arranged in a matrix form. A unit pixel refers to the minimum unit for implementing one color. A unit pixel of a flexible display may be implemented by a light emitting device. In the embodiment, the light emitting device may be Micro-LED or Nano-LED, but is not limited thereto.

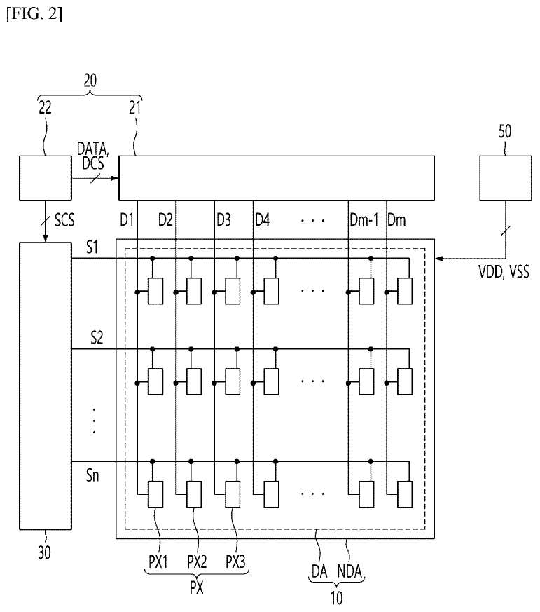

FIG. 2 is a block diagram schematically showing a display device according to an embodiment.

The display device 100 of the embodiment may drive the light emitting element in an active matrix (AM, Active Matrix) method or a passive matrix (PM, Passive Matrix) method. The driving circuit 20 may include a data driver 21 and a timing control unit 22.

The display panel 10 may be divided into a display area DA and a non-display area NDA disposed around the display area DA. The display area DA is an area in which pixels PX are formed to display an image. The display panel 10 may include data lines (D1 to Dm, m is an integer greater than or equal to 2), scan lines crossing the data lines D1 to Dm (S1 to Sn, n is an integer greater than or equal to 2), the high-potential voltage line supplied with the high-voltage, the low-potential voltage line supplied with the low-potential voltage, and the pixels PX connected to the data lines D1 to Dm and the scan lines S1 to Sn may be included.

Each of the pixels PX may include a first sub-pixel PX1, a second sub-pixel PX2, and a third sub-pixel PX3. The first sub-pixel PX1 emits a first color light of a first wavelength, the second sub-pixel PX2 emits a second color light of a second wavelength, and the third sub-pixel PX3 emits a third color light of a wavelength may be emitted. The first color light may be red light, the second color light may be green light, and the third color light may be blue light, but is not limited thereto. Also, although it is illustrated that each of the pixels PX includes three sub-pixels in FIG. 2, the present invention is not limited thereto. That is, each of the pixels PX may include four or more sub-pixels.

Each of the first sub-pixel (PX1), the second sub-pixel (PX2), and the third sub-pixel (PX3) may be connected to at least one of the data lines D1 to Dm, at least one of the scan lines S1 to Sn, and a high potential voltage line.

The driving circuit 20 outputs signals and voltages for driving the display panel 10. For this purpose, the driving circuit 20 may include a data driver 21 and a timing controller 22.

The data driver 21 receives digital video data (DATA) and source control signal (DCS) from the timing control unit 22. The data driver 21 converts digital video data (DATA) into analog data voltages according to the source control signal (DCS) and supplies them to the data lines (D1 to Dm) of the display panel 10.

The timing control unit 22 receives digital video data (DATA) and timing signals from the host system. Timing signals may include a vertical sync signal, a horizontal sync signal, a data enable signal, and a dot clock. The host system may be an application processor in a smartphone or tablet PC, a monitor, or a system-on-chip in a TV.

The scan driver 30 receives a scan control signal (SCS) from the timing control unit 22. The scan driver 30 generates scan signals according to the scan control signal SCS and supplies them to the scan lines S1 to Sn of the display panel 10. The scan driver 30 may include a plurality of transistors and may be formed in the non-display area NDA of the display panel 10. Alternatively, the scan driver 30 may be formed as an integrated circuit, and in this case, it may be mounted on a gate flexible film attached to the other side of the display panel 10.

The power supply circuit 50 generates a high potential voltage (VDD) and a low potential voltage (VSS) to drive the light emitting devices (LD) of the display panel 10 from the main power supply, so that may supply the high-potential voltage line and the low-potential voltage line of the display panel 10. Additionally, the power supply circuit 50 may generate and supply driving voltages for driving the driving circuit 20 and the scan driver 30 from the main power supply.

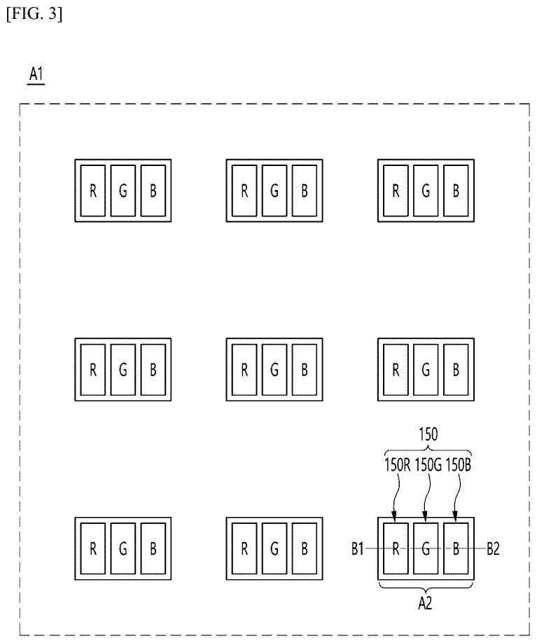

FIG. 3 is an enlarged view of the first panel area A1 in the display device of FIG. 1.

According to FIG. 3, the display device 100 of the embodiment may be manufactured by mechanically and electrically connecting a plurality of panel areas, such as the first panel area A1, by tiling.

The first panel area A1 may include a plurality of light emitting devices 150 arranged for each unit pixel (PX in FIG. 2).

For example, the unit pixel PX may include a first sub-pixel PX1, a second sub-pixel PX2, and a third sub-pixel PX3. For example, a plurality of red light emitting devices 150R are disposed in the first sub-pixel PX1, and a plurality of green light emitting devices 150G are disposed in the second sub-pixel PX2, a plurality of blue light emitting devices 150B may be disposed in the third sub-pixel PX3. The unit pixel PX may further include a fourth sub-pixel in which no light emitting device is disposed, but this is not limited. Meanwhile, the light emitting device 150 may be a semiconductor light emitting device.

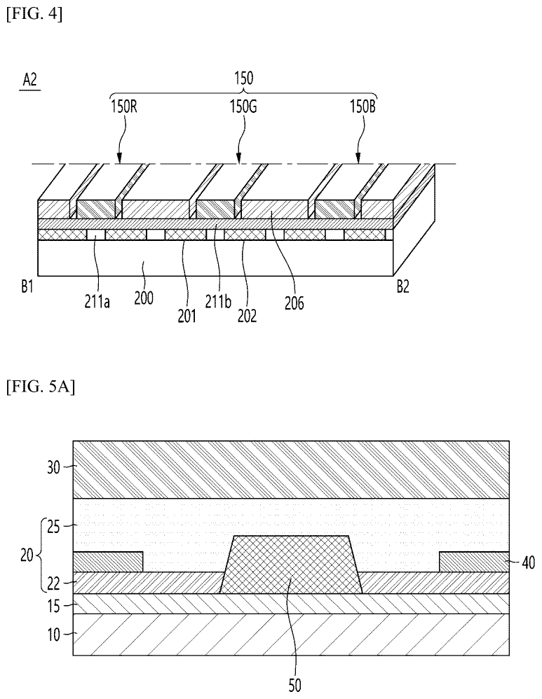

Next, FIG. 4 is a cross-sectional view taken along line B1-B2 in area A2 of FIG. 3.

Referring to FIG. 4, the display device 100 of the embodiment may include a substrate 200, assembly wiring 201 and 202, a first insulating layer 211a, a second insulating layer 211b, a third insulating layer 206, and a plurality of light emitting devices 150.

The assembly wiring may include a first assembly wiring 201 and a second assembly wiring 202 that are spaced apart from each other. The first assembly wiring 201 and the second assembly wiring 202 may be provided to generate dielectrophoretic force to assemble the light emitting device 150. Additionally, the first assembly wiring 201 and the second assembly wiring 202 may be electrically connected to the electrodes of the light emitting device and may function as electrodes of the display panel.

The assembly wiring 201 and 202 may be formed of a translucent electrode (ITO) or may contain a metal material with excellent electrical conductivity. For example, assembly wiring 201, 202 may be formed of at least one of titanium (Ti), chromium (Cr), nickel (Ni), aluminum (Al), platinum (Pt), gold (Au), tungsten (W), and molybdenum (Mo) or an alloy thereof.

The light emitting device 150 may include, but is not limited to, a red light emitting device 150, a green light emitting device 150G, and a blue light emitting device 150B0 to form a unit pixel (sub-pixel), and may include a red phosphor and a green phosphor to implement red and green colors, respectively.

The substrate 200 may be formed of glass or polyimide. Additionally, the substrate 200 may include a flexible material such as PEN (Polyethylene Naphthalate) or PET (Polyethylene Terephthalate). Additionally, the substrate 200 may be made of a light-transmitting material, but is not limited thereto.

The third insulating layer 206 may include an insulating and flexible material such as polyimide, PEN, PET, etc., and may be integrated with the substrate 200 to form one substrate.

The third insulating layer 206 may be a conductive adhesive layer that has adhesiveness and conductivity, and the conductive adhesive layer is flexible and may enable a flexible function of the display device. For example, the third insulating layer 206 may be an anisotropic conductive film (ACF) or a conductive adhesive layer such as an anisotropic conductive medium or a solution containing conductive particles. The conductive adhesive layer may be a layer that is electrically conductive in a direction perpendicular to the thickness, but electrically insulating in a direction horizontal to the thickness.

The third insulating layer 206 may include an assembly hole 203 into which the light emitting device 150 is inserted. Therefore, during self-assembly, the light emitting device 150 may be easily inserted into the assembly hole 203 of the third insulating layer 206. The assembly hole 203 may be called an insertion hole, a fixing hole, an alignment hole, etc.

The gap between the assembly wires 201 and 202 is formed to be smaller than the width of the light emitting device 150 and the width of the assembly hole 203, so that the assembly position of the light emitting device 150 using the badge may be fixed more precisely.

A third insulating layer 206 is formed on the assembly wiring 201 and 202, so that the assembly wirings 201 and 202 may be protected from the fluid 1200 and leakage of current flowing through the assembly wirings 201 and 202 may be prevented. The third insulating layer 206 may be formed as a single layer or multilayer of an inorganic insulator such as silica or alumina or an organic insulator.

Additionally, the third insulating layer 206 may include an insulating and flexible material such as polyimide, PEN, PET, etc., and may be integrated with the substrate 200 to form one substrate.

The third insulating layer 206 may be an adhesive insulating layer or a conductive adhesive layer with conductivity. The third insulating layer 206 is flexible and may enable a flexible function of the display device.

The third insulating layer 206 has a partition wall, and the assembly hole 203 may be formed by the partition wall. For example, when forming the substrate 200, a portion of the third insulating layer 206 is removed, so that each of the light emitting devices 150 may be assembled into the assembly hole 203 of the third insulating layer 206.

An assembly hole 203 where the light emitting devices 150 are coupled is formed in the substrate 200, and the surface where the assembly hole 203 is formed may be in contact with the fluid 1200. The assembly hole 203 may guide the exact assembly position of the light emitting device 150.

Meanwhile, the assembly hole 203 may have a shape and size corresponding to the shape of the light emitting device 150 to be assembled at the corresponding location. Accordingly, it is possible to prevent another light emitting device from being assembled in the assembly hole 203 or a plurality of light emitting devices from being assembled.

Hereinafter, a display device including the semiconductor light emitting device according to an embodiment for solving technical problems will be described with reference to the drawings.

A display device including the semiconductor light emitting device according to an embodiment may use the self-assembly method using the dielectrophoresis force (DEP force) described above, and also the pick-and-place assembly method and the stamp method may be used.

FIGS. 5A and 5B are graphs showing the conceptual diagram and luminance of a display device that is being studied internally.

Referring to FIG. 5A, a semiconductor light emitting device 50 may be disposed on the substrate 10. Additionally, a transparent filler layer 20 may be disposed to cover the semiconductor light emitting device 50. Meanwhile, an opaque filler 40 may be disposed on the transparent filler layer 20. The opaque filler 40 may be a black matrix. The opaque filler 40 may be positioned higher than the lower surface of the semiconductor light emitting device 50 and may be arranged to be spaced apart. The opaque filler 40 may prevent color mixing between pixels. Meanwhile, referring to FIG. 5B, when the opaque filler is located on the top of the semiconductor light emitting device 50, the luminance difference may increase depending on the viewing angle. The luminance varies depending on the position and angle of the semiconductor light emitting device and the opaque filler, and as a result, there is a problem in that light uniformity is deteriorated.

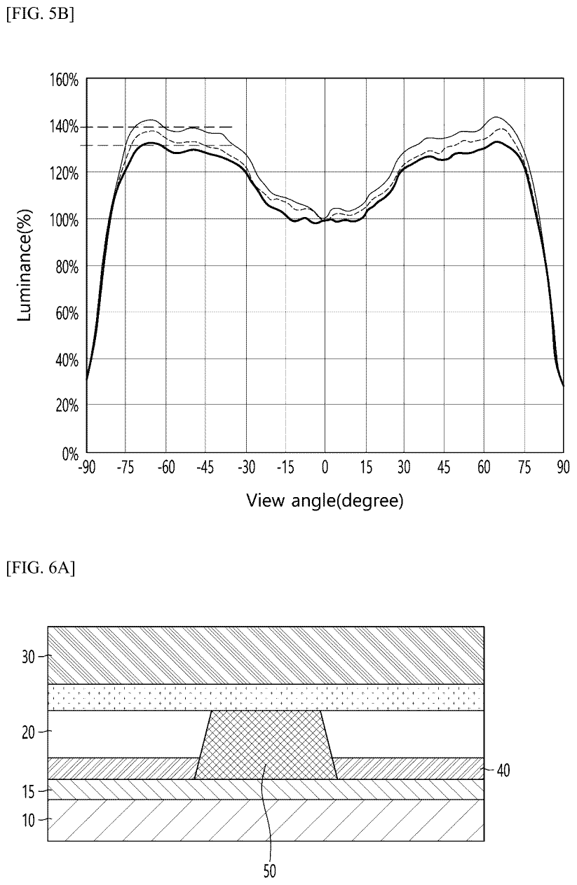

Additionally, referring to FIG. 6A, an opaque filler 40 may be disposed to surround the semiconductor light emitting device 50. The opaque filler 40 may be in contact with the side surface of the semiconductor light emitting device. Additionally, the opaque filler may be located lower than the top surface of the semiconductor light emitting device. Meanwhile, referring to FIG. 6B, the display device of FIG. 6A may secure uniformity by having a small luminance deviation depending on the viewing angle, but there is a problem in that luminance is reduced due to light absorption by the opaque filler.

Accordingly, there is a problem in that it is difficult to improve both luminance and light uniformity when only the opaque filler is located on top of the semiconductor light emitting device or when it surrounds the semiconductor light emitting device. However, since display devices using ultra-small micro LEDs require both luminance and light uniformity characteristics, an embodiment that may solve the above problems will be described below.

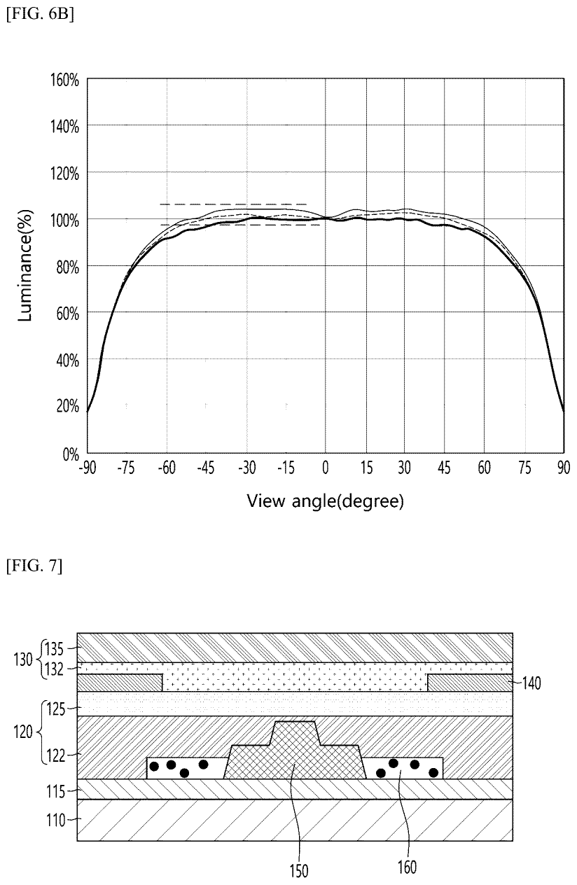

FIG. 7 is a conceptual diagram of a display device including the semiconductor light emitting device according to an embodiment. Referring to FIG. 7, an adhesive layer 115 may be disposed on the substrate 110. The semiconductor light emitting device 150 may be disposed by being adhered to the adhesive layer 115.

Additionally, a planarization layer 120 may be disposed on the adhesive layer 115. The planarization layer 120 may be called a transparent filling layer filled with a transparent material. Additionally, the planarization layer 120 may have insulating properties.

The planarization layer 120 may include a first planarization layer 122 and a second planarization layer 125. The planarization layer 120 may be disposed to cover the semiconductor light emitting device 150. In FIG. 9, although the semiconductor light emitting device 150 is shown in contact with the first planarization layer 122 and the second planarization layer 125, the semiconductor light emitting device 150 may be located within the first planarization layer 122.

Meanwhile, a light reflective filling layer 160 may be disposed to surround the semiconductor light emitting device 150. The light reflective filling layer 160 may be filled with a material having a high refractive index. For example, the light reflective filling layer may include at least one of TiO2 or ZrO2, but is not limited thereto. Additionally, the light reflective filling layer 160 may include a photosensitive material and may have a light reflectance of 60% or more. Therefore, in the embodiment, as the light reflective filling layer is arranged to surround the semiconductor light emitting device, there is a technical effect of improving light efficiency by reflecting light exiting the side and bottom of the semiconductor light emitting device upward.

Additionally, the light reflective filling layer 160 may be located lower than the semiconductor light emitting device 150. The lower surface of the light reflective filling layer 160 may be located at the same height as the lower surface of the semiconductor light emitting device 150, the top surface of the light reflective filling layer 160 may be located lower than the top surface of the semiconductor light emitting device 150. Additionally, a thickness of the light reflective filling layer 160 may be smaller than a thickness of the semiconductor light emitting device 150. The semiconductor light emitting device 150 and the light reflective filling layer 160 may be covered by a planarization layer 120.

The side surface of the semiconductor light emitting device 150 may include a first area in contact with the light reflective filling layer 160 and a second area in contact with the planarization layer 120. The light reflective filling layer 160 may be located within the first planarization layer 122.

Meanwhile, one or more first opaque fillers 140 may be disposed on the planarization layer 120. The one or more first opaque fillers 140 may include a black-based color or a black matrix. The one or more first opaque filler 140 may prevent light leakage in the display device and prevent color mixing between pixels.

In addition, the one or more first opaque filler 140 may include a plurality of pieces and be arranged to be spaced apart from each other. The semiconductor light emitting device 150 may be located below the one or more first opaque fillers 140. The semiconductor light emitting device 150 may not vertically overlap the one or more first opaque fillers 140. Additionally, the semiconductor light emitting device 150 may not overlap the one or more first opaque fillers 140 in the horizontal direction. Additionally, the horizontal width of the light reflective filling layer 160 may be greater than the distance between the plurality of first opaque fillers. A portion of the light reflecting filling layer 160 may vertically overlap the one or more first opaque filling fillers 140.

Additionally, an insulating layer 130 may be disposed on the planarization layer 120. The insulating layer 130 may be called a cover layer. The insulating layer 130 may include a first insulating layer 132 and a second insulating layer 135 disposed on the first insulating layer 132. The first opaque filler 140 may be disposed within or on the first insulating layer 132.

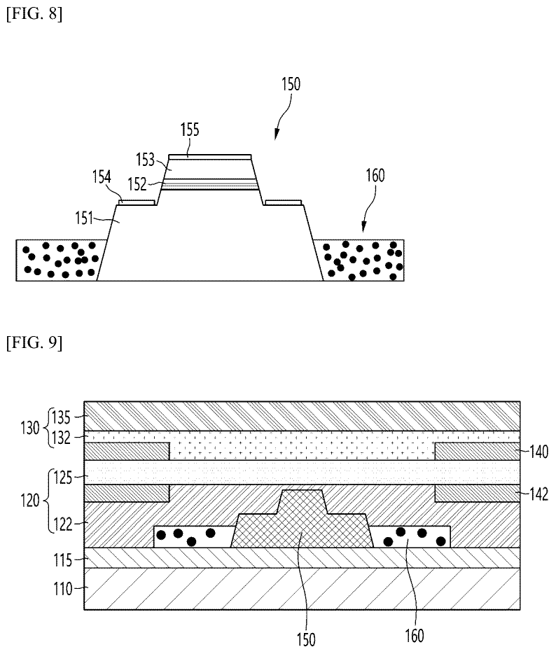

FIG. 8 is a conceptual diagram showing in detail the semiconductor light emitting device 150 of FIG. 7 according to an embodiment. Referring to FIG. 8, the semiconductor light emitting device 150 may be a semiconductor light emitting device with a horizontal structure, but is not limited thereto. The semiconductor light emitting device 150 may include a first conductivity type semiconductor layer 151, an active layer 152, a second conductivity type semiconductor layer 153, a first electrode 154, and a second electrode 155. The first conductivity type semiconductor layer 151 may be an n-type semiconductor layer, and the second conductivity type semiconductor layer 153 may be a p-type semiconductor layer, but are not limited thereto. The first conductivity type semiconductor layer 151, the active layer 152, and the second conductivity type semiconductor layer 153 may be made of a compound semiconductor material. For example, the compound semiconductor material may be a group III-V compound semiconductor material, a group II-VI compound semiconductor material, etc. For example, the compound semiconductor may be may be selected from the group including of a binary compound selected from the group including of GaP, GaAs, GaSb, AlP, AlAs, AlSb, InP, InAs, InSb and mixtures thereof, a three-element compound selected from the group including of GaNP, GaNAs, GaNSb, GaPAs, GaPSb, AlInP, AlNP, AlNAs, AlNSb, AlPAS, AlPSb, InNP, InNAs, InNSb, InPAs, InPSb, GaAlNP and mixtures thereof and quaternary compounds selected from the group including of AlGaInP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb and mixtures thereof. For example, the first conductivity type semiconductor layer 151 may include a first conductivity type dopant, and the second conductivity type semiconductor layer 153 may include a second conductivity type dopant. For example, the first conductivity type dopant may be an n-type dopant such as silicon (Si), and the second conductivity type dopant may be a p-type dopant such as boron (B).

The active layer 152 may be a region that generates light, and may generate light with a specific wavelength band depending on the material properties of the compound semiconductor. Additionally, the active layer may have a multiple quantum well or single quantum well structure, and the wavelength band may be determined by the energy band gap of the compound semiconductor included in the active layer. Therefore, depending on the energy band gap of the compound semiconductor included in the active layer, the semiconductor light emitting device of the embodiment may generate UV light, blue light, green light, and red light.

In addition, a power source may be connected to each of the first electrode 154 and the second electrode 155 of the semiconductor light emitting device 150 to drive the semiconductor light emitting device 150.

Additionally, a light reflective filling layer 160 may be disposed to surround the semiconductor light emitting device 150. The light reflective filling layer 160 may be located lower than the active layer 152. Additionally, the thickness of the light reflective filling layer 160 may be smaller than the thickness of the semiconductor light emitting device 150. The side surface of the semiconductor light emitting device 150 may include a first area in contact with the light reflective filling layer 160 and a second area in contact with the planarization layer. Additionally, the light reflective filling layer 160 may be in contact with the side surface of the first conductivity type semiconductor layer 151 of the semiconductor light emitting device 150.

Accordingly, in this embodiment, as the light reflective filling layer is located lower than the active layer of the semiconductor light emitting device, so that there is a technical effect of improving light efficiency by reflecting light emitted from the lower and side portions of the semiconductor light emitting device upward.

FIG. 9 is a conceptual diagram of a display device including the semiconductor light emitting device according to a second embodiment. Referring to FIG. 9, the second embodiment may further include one or more second opaque fillers 142 disposed within the planarization layer 120. The one or more second opaque fillers 142 may be disposed within the first planarization layer 122 or on the first planarization layer 122.

The one or more second opaque fillers 142 may be arranged to be vertically spaced apart from the first opaque filler 140. The one or more second opaque fillers 142 and the one or more first opaque fillers 140 may be disposed with the second planarization layer 125 interposed therebetween. Additionally, the one or more second opaque fillers 142 and the one or more first opaque fillers 140 may be arranged to overlap vertically.

Meanwhile, the one or more first opaque fillers 140 may cover the light leak of light emitted at a relatively high angle, and the one or more second opaque fillers 142 may cover the light leak of light emitted at a relatively low angle.

Therefore, in the second embodiment, the one or more first opaque fillers and the one or more second opaque fillers may be arranged to overlap vertically, when the spacing between semiconductor light emitting devices can be miniaturized, there is a technical effect of further preventing color mixing between a plurality of semiconductor light emitting devices.

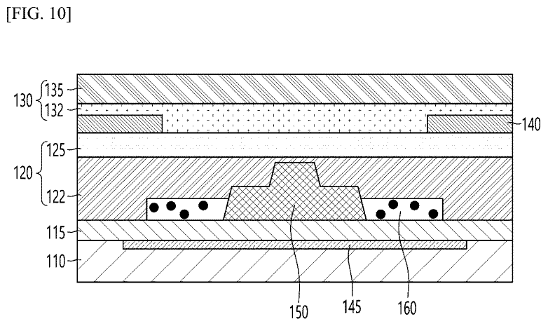

FIG. 10 is a conceptual diagram of a display device including the semiconductor light emitting device according to a third embodiment. Referring to FIG. 10, the third embodiment may further include a reflective film 145 disposed below the semiconductor light emitting device 150. The reflective film 145 may be disposed between the substrate 110 and the adhesive layer 115. Additionally, the light reflective filling layer 160 may be positioned between the first opaque filler 140 and the reflective film 145.

The horizontal width of the reflective film 145 may be larger than the gap between the first opaque fillers 140. Additionally, the horizontal width of the reflective film 145 may be larger than the horizontal width of the light reflective filling layer 160. Accordingly, the embodiment has the technical effect of further improving light efficiency by reflecting light emitted from the bottom of the semiconductor light emitting device 150 toward the top.

A display device including the semiconductor light emitting device according to an embodiment has the technical effect of improving light uniformity.

For example, the embodiment may reduce the difference in luminance depending on the viewing angle by disposing a light reflective filling layer surrounding the semiconductor light emitting device.

Additionally, the embodiment has a technical effect of improving the brightness of the display device.

For example, as the light reflective filling layer is located lower than the semiconductor light emitting device, light emitted from the sides and bottom of the semiconductor light emitting device may be reflected upward to improve luminance.

The above has been described with reference to embodiments of the present invention, those skilled in the art will easily understand that various modifications and changes may be made to the present invention without departing from the spirit and scope of the present invention as set forth in the claims below.

[Explanation of refence signs]

| | |
|---|---|
| 110: substrate | 115: adhesive layer |
| 120: planarization layer | 122: first planarization layer |
| 125: second planarization layer | 130: insulating layer |
| 132: first insulating layer | 135: second insulating layer |
| 140: first opaque filler | 142: second opaque filler |
| 145: reflective film | 150: semiconductor light |
| | emitting device |
| 160: light reflective filling layer | |

What is claimed is:

1. A display device including a semiconductor light emitting device comprising:
a substrate;
a semiconductor light emitting device disposed on the substrate;
a planarization layer disposed on the semiconductor light emitting device;
one or more first opaque fillers disposed to be spaced apart on the planarization layer, and
a light reflective filling layer disposed around the semiconductor light emitting device,
wherein the light reflective filling layer is positioned lower than a top surface of the semiconductor light emitting device.

2. The display device including the semiconductor light emitting device according to claim 1, wherein a side surface of the semiconductor light emitting device comprises a first area in contact with the light reflective filling layer and a second area in contact with the planarization layer.

3. The display device including the semiconductor light emitting device according to claim 1, wherein the semiconductor light emitting device is located below between the first opaque fillers.

4. The display device including the semiconductor light emitting device according to claim 3, wherein the semiconductor light emitting device does not vertically overlap the first opaque fillers.

5. The display device including the semiconductor light emitting device according to claim 1, wherein a horizontal width of the light reflective filling layer is greater than a distance between the first opaque fillers.

6. The display device including the semiconductor light emitting device according to claim 1, further comprising a reflective film disposed below the semiconductor light emitting device.

7. The display device including the semiconductor light emitting device according to claim 6, wherein a horizontal width of the reflective film is greater than a distance between the first opaque fillers spaced apart.

8. The display device including the semiconductor light emitting device according to claim 1, wherein a lower surface of the light reflective filling layer is located at the same height as a lower surface of the semiconductor light emitting device, and an upper surface of the light reflective filling layer is located lower than an active layer of the semiconductor light emitting device.

9. The display device including the semiconductor light emitting device according to claim 1, wherein a thickness of the light reflective filling layer is smaller than a thickness of the semiconductor light emitting device.

10. The display device including the semiconductor light emitting device according to claim 1, further comprising one or more second opaque fillers disposed below the first opaque fillers.

11. The display device including the semiconductor light emitting device according to claim 1, wherein the one or more second opaque fillers are disposed on the planarization layer.

12. The display device including the semiconductor light emitting device according to claim 1, wherein a reflectance of the light reflective filling layer is 60% or more.

13. The display device including the semiconductor light emitting device according to claim 1, wherein the light reflective filling layer comprises either TiO₂ or ZrO₂.

14. The display device including the semiconductor light emitting device according to claim 6, wherein a horizontal width of the reflective film is greater than the horizontal width of the light reflective filling layer.

15. The display device including the semiconductor light emitting device according to claim 10, wherein further comprising a second planarization layer disposed between the first opaque fillers and the second opaque fillers.

16. A display device including a semiconductor light-emitting device comprising:
a substrate;
a semiconductor light-emitting device disposed on the substrate;
a planarization layer disposed on an upper side of the semiconductor light-emitting device;
one or more first opaque fillers on the planarization layer;
one or more second opaque fillers disposed below the first opaque fillers and disposed in the planarization layer; and
a light reflective filling layer disposed around the semiconductor light-emitting device.

17. The display device including the semiconductor light-emitting device according to the claim 16,
wherein the light reflective filling layer is disposed lower than an upper surface of the semiconductor light-emitting device.

18. The display device including the semiconductor light-emitting device according to the claim 16, wherein the light reflective filling layer comprises a reflectivity of 60% or more.

19. The display device including the semiconductor light-emitting device according to the claim 16, further comprising a second planarization layer disposed between the one or more first opaque fillers and the one or more second opaque fillers.

20. The display device including the semiconductor light-emitting device according to the claim 16, further comprising a reflective film disposed under the semiconductor light-emitting device.
